(19) United States
(12) Patent Application Publication
(10) Pub. No.: US 2026/0011621 A1
(43) Pub. Date: Jan. 8, 2026

(54) SEMICONDUCTOR PACKAGE

(71) Applicant: Samsung Electronics Co., Ltd., Suwon-si (KR)

(72) Inventors: Junghoon Kang, Suwon-si (KR); Jihye Shim, Suwon-si (KR)

(21) Appl. No.: 19/007,917

(22) Filed: Jan. 2, 2025

(30) Foreign Application Priority Data
Jul. 5, 2024 (KR) 10-2024-0089024

(51) Int. Cl. H01L 23/373; H01L 23/00; H01L 25/00; H01L 25/03

(52) U.S. Cl. CPC H01L 23/3735; H01L 24/32; H01L 25/03; H01L 25/50; H01L 24/20; H01L 24/73; H01L 2224/211; H01L 2224/32056; H01L 2224/32225; H01L 2224/73267

(57) ABSTRACT

A semiconductor package includes: a lower redistribution structure including a lower redistribution layer; external connection bumps below the lower redistribution structure; a lower chip structure on the lower redistribution structure; an encapsulant at least partially encapsulating the lower chip structure; an upper encapsulating layer on the encapsulant; an adhesive layer on an upper surface of the lower chip structure; a plurality of posts extending through the encapsulant and electrically connected to the lower redistribution layer; an upper chip structure on the upper encapsulating layer and electrically connected to the plurality of posts; a heat dissipation member on one side of the upper chip structure and overlapping the lower chip structure in a vertical direction; and a heat transfer material layer extending through the upper encapsulating layer and the adhesive layer and disposed between the heat dissipation member and the lower chip structure.

### CROSS-REFERENCE TO RELATED APPLICATION(S)

This application claims benefit of priority to Korean Patent Application No. 10-2024-0089024, filed on Jul. 5, 2024 in the Korean Intellectual Property Office, the disclosure of which is incorporated herein by reference in its entirety.

### BACKGROUND

The present inventive concept relates to a semiconductor package.

As electronic devices become lighter and more high-performance, the development of miniaturized and high-performance semiconductor chips is required. In order to improve reliability of the high-performance semiconductor chips, importance of heat dissipation characteristics of semiconductor packages is increasing.

### SUMMARY

An aspect of the present inventive concept is to provide a semiconductor package having improved reliability.

According to an aspect of the present inventive concept, a semiconductor package includes: a lower redistribution structure including a lower redistribution layer; external connection bumps below the lower redistribution structure and electrically connected to the lower redistribution layer; a lower chip structure on the lower redistribution structure and electrically connected to the lower redistribution layer; an encapsulant at least partially encapsulating the lower chip structure; an upper encapsulating layer on the encapsulant; an adhesive layer on an upper surface of the lower chip structure and fixing the lower chip structure to the upper encapsulating layer; a plurality of posts extending through the encapsulant and electrically connected to the lower redistribution layer; an upper chip structure on the upper encapsulating layer and electrically connected to the plurality of posts; a heat dissipation member on one side of the upper chip structure and overlapping the lower chip structure in a vertical direction; and a heat transfer material layer extending through the upper encapsulating layer and the adhesive layer and disposed between the heat dissipation member and the lower chip structure.

According to an aspect of the present inventive concept, a semiconductor package includes: a lower package structure including a lower chip structure, an adhesive layer on the lower chip structure, and an upper encapsulating layer on the adhesive layer and including a photosensitive resin composition; a heat dissipation member on the lower package structure and overlapping the lower chip structure in a vertical direction; an upper chip structure on the lower package structure and spaced apart from the heat dissipation member; and a heat transfer material layer between the lower chip structure and the heat transfer material layer and extending through the upper encapsulating layer and the adhesive layer, wherein the heat transfer material layer, the adhesive layer, and the upper encapsulating layer are in contact with each other at an upper edge of an internal side surface of the adhesive layer.

According to an aspect of the present inventive concept, a semiconductor package includes: a lower package structure including a lower redistribution structure, a lower chip structure on the lower redistribution structure, an upper encapsulating layer on the lower chip structure, and a plurality of posts electrically connected to the lower redistribution structure; a heat dissipation member and an upper chip structure adjacent each other on the lower package structure; a heat transfer material layer between the lower chip structure and the heat dissipation member and extending through the upper encapsulating layer; and upper connection bumps extending through the upper encapsulating layer and electrically connecting the plurality of posts and the upper chip structure.

According to an aspect of the present inventive concept, a method for manufacturing a semiconductor device includes: forming a laser debonding layer on a carrier substrate; forming a plurality of posts on the laser debonding layer; forming an adhesive layer on an upper surface of a lower chip structure and joining the adhesive layer and the laser debonding layer, to settle the lower chip structure; forming an encapsulant at least partially embedding the lower chip structure and the plurality of posts, and forming a lower redistribution structure; separating the carrier substrate by the laser debonding layer, by irradiating a laser to penetrate the carrier substrate; forming a cavity penetrating through the laser debonding layer and the adhesive layer from an upper surface of the laser debonding layer; and forming a heat transfer material layer within the cavity, and positioning a heat dissipation member on the heat transfer material layer.

### BRIEF DESCRIPTION OF DRAWINGS

The above and other aspects, features, and advantages of the present inventive concept will be more clearly understood from the following detailed description, taken in conjunction with the accompanying drawings, in which:

FIG. 1 is a plan view of a semiconductor package according to example embodiments.

FIG. 2 is a cross-sectional view of the semiconductor package of FIG. 1, taken along line I-I′.

FIG. 3 is a partial enlarged view of the semiconductor package of FIG. 2.

FIGS. 4A and 4B are cross-sectional views illustrating example embodiments of a lower chip structure applicable to the semiconductor package of FIG. 1.

FIG. 4C is a cross-sectional view illustrating an upper chip structure applicable to the semiconductor package of FIG. 1 according to example embodiments.

FIGS. 5 to 10 are cross-sectional views of a semiconductor package according to example embodiments.

FIGS. 11A to 11J are cross-sectional views illustrating a process of manufacturing a semiconductor package according to example embodiments.

### DETAILED DESCRIPTION

Hereinafter, example embodiments will be described with reference to the attached drawings. Unless otherwise specifically stated, in this specification, terms such as ‘on,’ ‘upper,’ ‘upper portion,’ ‘upper surface,’ ‘below,’ ‘lower,’ ‘lower portion,’ ‘lower surface,’ ‘side surface,’ and the like may be based on the drawings, and may actually be changed, depending on a direction in which components are arranged.

In addition, ordinal numbers such as “first,” “second,” “third,” and the like may be used as labels for specific elements, operations, directions, and the like to distinguish between various elements, operations, directions, and the like. Terms that may not be described using “first”, “second”, etc. in the specification may still be referred to as “first,” “second,” and the like in the claims. In addition, terms that may be referenced by a specific ordinal number (e.g., “first” in a particular claim) may be described elsewhere by a different ordinal number (e.g., “second” in the specification or another claim).

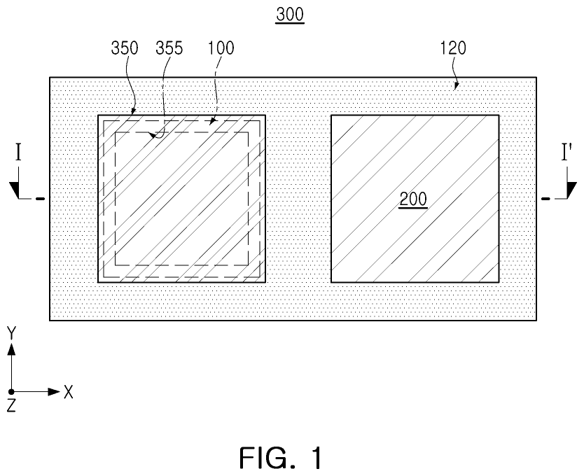

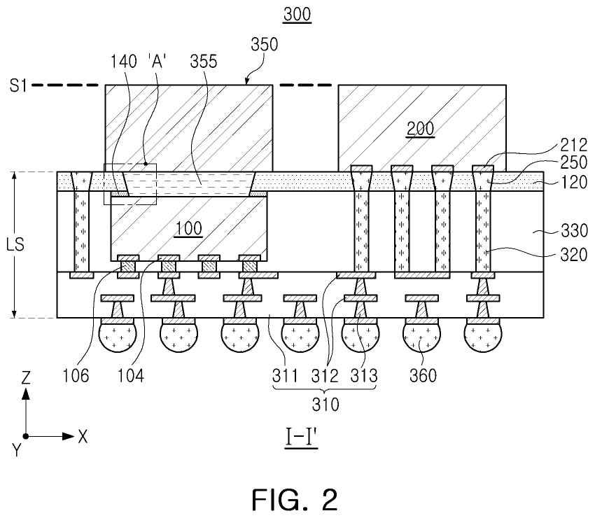

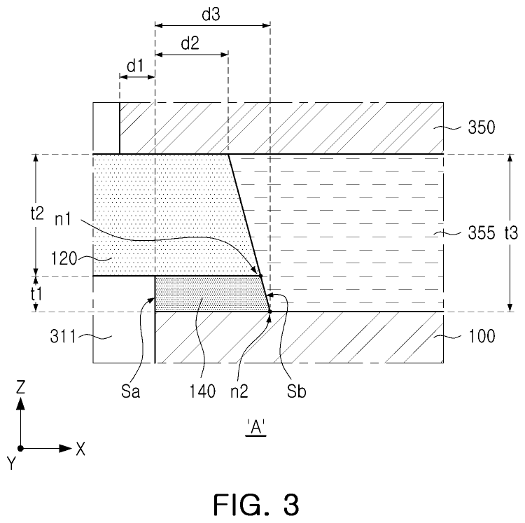

FIG. 1 is a plan view of a semiconductor package according to example embodiments, FIG. 2 is a cross-sectional view of the semiconductor package of FIG. 1, taken along line I-I′, and FIG. 3 is an enlarged view of portion ‘A’ of the semiconductor package of FIG. 2.

Referring to FIGS. 1 to 3, a semiconductor package 300 may include a lower package structure LS, an upper chip structure 200, and a heat dissipation member 350. The upper chip structure 200 and the heat dissipation member 350 may be arranged on the lower package structure LS to be spaced apart from each other, but adjacent to each other. The lower package structure LS may include a lower chip structure 100, a lower redistribution structure 310, a plurality of posts 320, an encapsulant 330, and an upper encapsulating layer 120.

The lower chip structure 100 may be disposed on the lower redistribution structure 310 and may include first connection terminals 104 electrically connected to a lower redistribution layer 312. The first connection terminals 104 may be connected to the lower redistribution layer 312 through lower connection posts 106 disposed between the lower chip structure 100 and the lower redistribution structure 310.

The upper chip structure 200 may be disposed on the upper encapsulating layer 120. The upper chip structure 200 may be electrically connected to the lower redistribution layer 312 through upper connection bumps 250 and the plurality of posts 320. The upper chip structure 200 may include second connection terminals 212 electrically connected to the upper connection bumps 250. The second connection terminals 212 may be connected to the plurality of posts 320 through the upper connection bumps 250 disposed in the upper encapsulating layer 120. An underfill material layer (not illustrated) surrounding the upper connection bumps 250 may be formed below the upper chip structure 200.

The upper chip structure 200 may be disposed to vertically overlap at least some posts 320 among the plurality of posts 320. In addition, the upper chip structure 200 may be disposed to be staggered or offset from the lower chip structure 100 in a horizontal direction, to expose at least a portion of the lower chip structure 100 in a vertical direction (Z-direction). The upper chip structure 200 may be disposed on one side of the heat dissipation member 350 disposed above the lower chip structure 100 and spaced apart from the heat dissipation member 350. In other words, the upper chip structure 200 may be disposed on one side of and spaced apart from the heat dissipation member 350. In such a configuration, the heat dissipation member 350 may be disposed above or vertically overlap the lower chip structure 100.

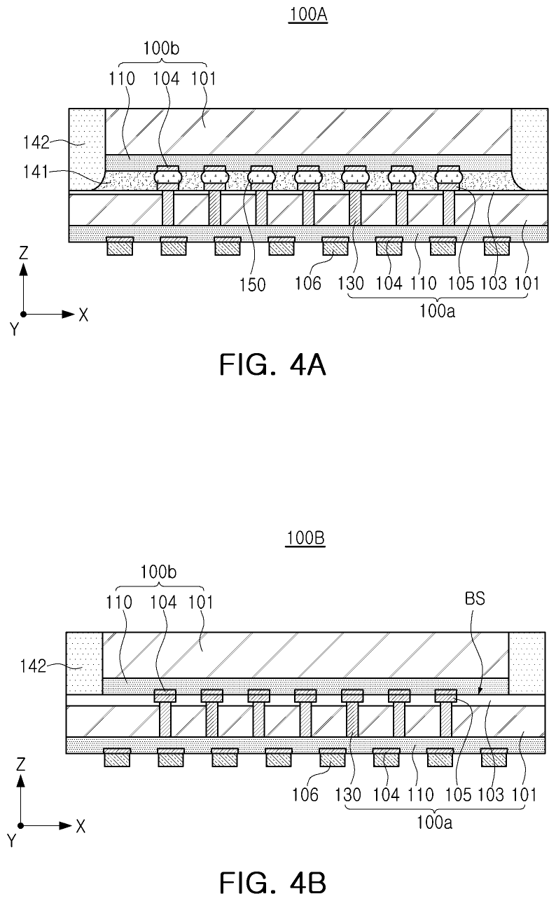

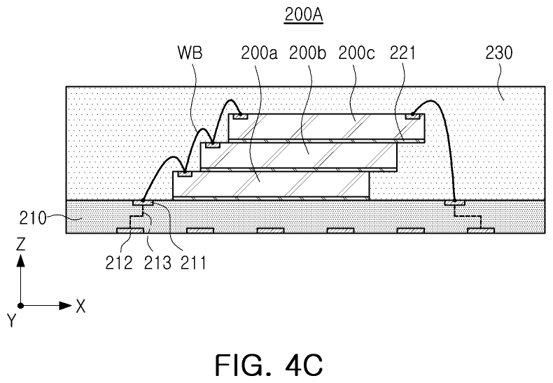

The lower chip structure 100 and the upper chip structure 200 may include a semiconductor wafer and a semiconductor wafer integrated circuit (IC), formed of a semiconductor element such as silicon, germanium, or the like, or a compound semiconductor such as silicon carbide (SiC), gallium arsenide (GaAs), indium arsenide (InAs), indium phosphide (InP), or the like. The lower chip structure 100 and the upper chip structure 200 may be bare semiconductor chips without separate bumps or interconnection layers, but the present inventive concept is not limited thereto. For example, the lower chip structure 100 and the upper chip structure 200 may also be packaged type semiconductor chips. The integrated circuit may be a logic circuit (or ‘logic chip’) such as a central processor (CPU), a graphic processor (GPU), a field programmable gate array (FPGA), an application processor (AP), a digital signal processor, an encryption processor, a microprocessor, a microcontroller, an analog-to-digital converter, an application-specific IC (ASIC), or the like, or a memory circuit (or ‘memory chip’) including a volatile memory such as a dynamic RAM (DRAM), a static RAM (SRAM), or the like, or a non-volatile memory such as a phase change RAM (PRAM), a magnetic RAM (MRAM), a resistive RAM (RRAM), a flash memory, or the like. The lower chip structure 100 and the upper chip structure 200 may include different types of semiconductor chips. For example, the lower chip structure 100 may include at least one logic chip, and the upper chip structure 200 may include at least one memory chip. According to some embodiments, the lower chip structure 100 and the upper chip structure 200 may each be a package structure including a plurality of semiconductor chips, which will be described below with reference to FIGS. 4A to 4C.

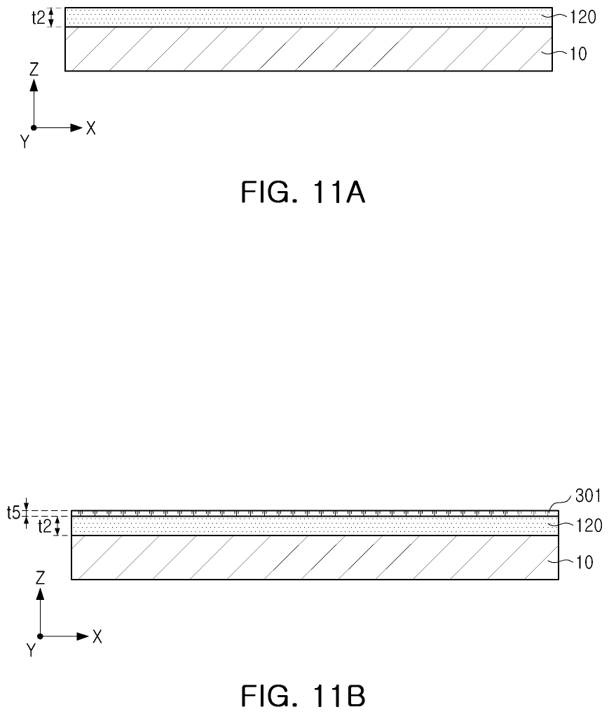

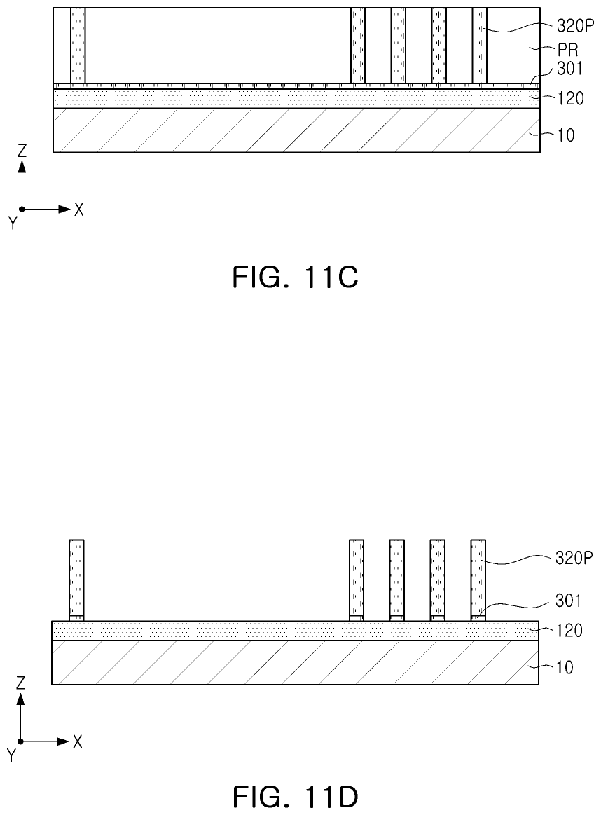

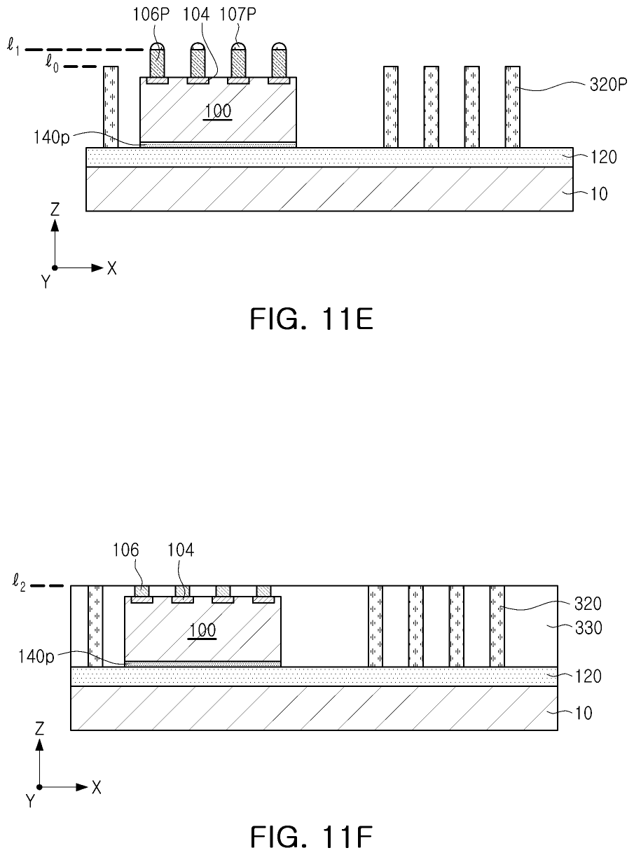

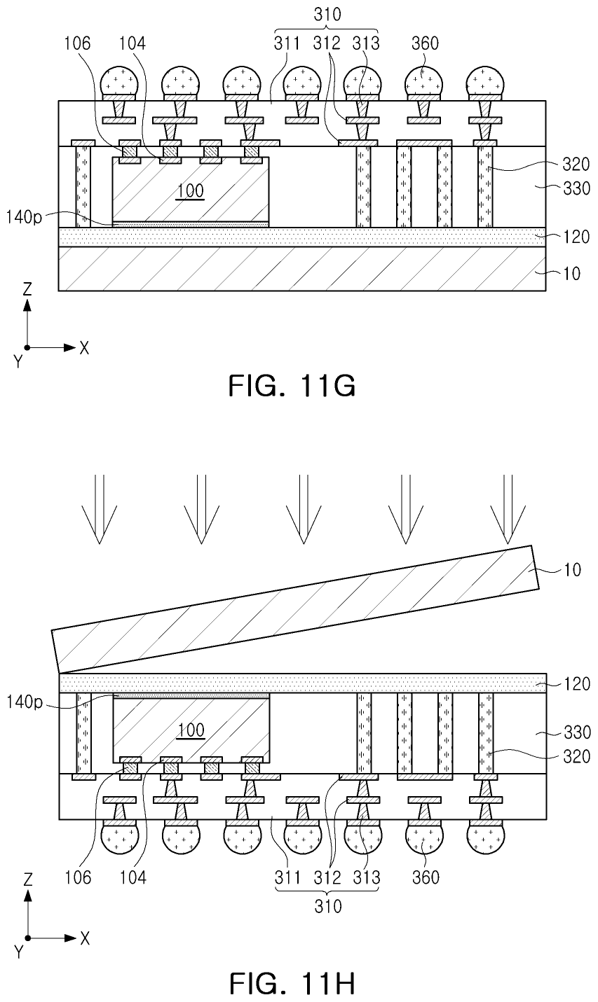

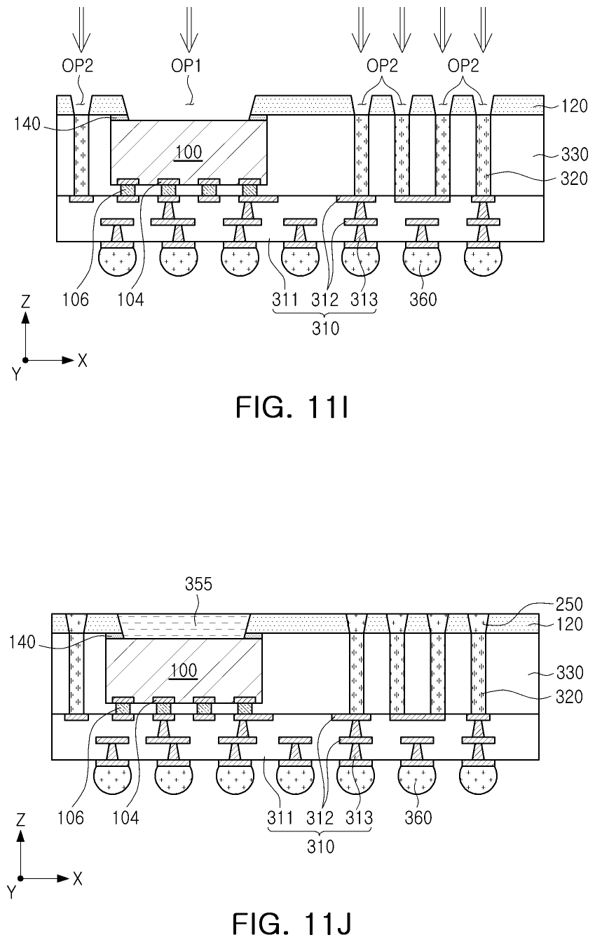

An adhesive layer 140 for adhering to the upper encapsulating layer 120 may be further disposed on an upper surface of the lower chip structure 100. The adhesive layer 140 may be an adhesive material for die bonding for mounting the lower chip structure 100 on the upper encapsulating layer 120 of a carrier substrate 10 (see e.g., the carrier substrate 10 of FIG. 11F), and may include a paste including a metal such as gold or silver, a paste including silver, a liquid epoxy resin, a polyimide resin, or the like. In addition, a die attach film (DAF) may be applied as the adhesive layer 140. A first thickness t1 of the adhesive layer 140 may be smaller than a second thickness t2 of the upper encapsulating layer 120, and the adhesive layer 140 may include the same material as the upper encapsulating layer 120, but the present inventive concept is not limited thereto.

The adhesive layer 140 may not be entirely disposed on the upper surface of the lower chip structure 100; for example, it may instead be disposed only on an edge region of the lower chip structure 100. For example, the adhesive layer 140 may be disposed along the edge region on the upper surface of the lower chip structure 100 to have a frame shape. The adhesive layer 140 in the frame shape may include an upper surface contacting a lower surface of the upper encapsulating layer 120, a lower surface contacting the upper surface of the lower chip structure 100, an external side surface or outer side surface Sa exposed externally, and an internal side surface or inner side surface Sb facing a center or an opening of the frame shape. The external side surface Sa may be disposed to be aligned with or coplanar with a side surface of the lower chip structure 100 in a Z-direction, and the internal side surface Sb may have an incline. If a distance between the internal side surface Sb and the external side surface Sa is defined as a width, a width of the upper surface and a width of the lower surface of the adhesive layer 140 may be different from each other, and the width may increase toward the lower surface due to the incline of the internal side surface Sb.

The lower redistribution structure 310 may be disposed below the lower chip structure 100, and may include a lower insulating layer 311, lower redistribution layers 312, and a lower redistribution via 313.

The lower insulating layer 311 may include an insulating resin. The insulating resin may include a thermosetting resin such as an epoxy resin, a thermoplastic resin such as a polyimide, or a resin in which an inorganic filler is impregnated thereinto, such as a prepreg, an Ajinomoto build-up film (ABF), an FR-4, or bismaleimide-triazine (BT). For example, the lower insulating layer 311 may include a photosensitive resin such as a photoimageable dielectric (PID). The lower insulating layer 311 may include a plurality of insulating layers stacked in the vertical direction (Z-axis direction). Depending on a process, a boundary between the plurality of insulating layers may be unclear. In other words, depending on how the lower insulating layer 311 is manufactured, any of the plurality of insulating layers may not have clear boundaries between them and any of the other plurality of insulating layers.

The lower redistribution layer 312 may be disposed on or in the lower insulating layer 311 and may redistribute the first connection terminal 104 of the lower chip structure 100. The lower redistribution layer 312 may include a metal, for example, copper (Cu), aluminum (Al), silver (Ag), tin (Sn), gold (Au), nickel (Ni), lead (Pb), titanium (Ti), or alloys thereof. The lower redistribution layer 312 may perform various functions depending on a design. For example, the lower redistribution layer 312 may include a ground pattern, a power pattern, and a signal pattern. In this case, the signal pattern may provide a transmission path for various signals, for example, a data signal, excluding the ground pattern, the power pattern, or the like. The lower redistribution layer 312 may include more or fewer redistribution layers than those illustrated in the drawings. The lower redistribution layer 312 may include redistribution pads exposed from an upper surface of the lower redistribution structure 310. The redistribution pads may be electrically connected to the lower connection bumps 106 connected to the plurality of posts 320 and the first connection terminals 104 of the lower chip structure 100.

The lower redistribution via 313 may extend vertically in the lower insulating layer 311 and may be electrically connected to the lower redistribution layer 312. For example, the lower redistribution via 313 may interconnect the lower redistribution layers 312 on different levels. The lower redistribution via 313 may include a signal via, a ground via, and a power via. The lower redistribution via 313 may include a metal material, for example, copper (Cu), aluminum (Al), silver (Ag), tin (Sn), gold (Au), nickel (Ni), lead (Pb), titanium (Ti), or alloys thereof. The lower redistribution via 313 may be a filled via in which a metal material is filled inside a via hole or a may be conformal via in which a metal material extends along an inner wall of a via hole.

External connection bumps 360 may be disposed below the lower redistribution structure 310. The external connection bumps 360 may be electrically connected to the lower redistribution layer 312. The semiconductor package 300 may be connected to an external device, such as a module substrate, a system board, or the like through the external connection bumps 360. The external connection bumps 360 may have a form in which a pillar (or underbump metal) and a ball are combined. The pillar may include copper (Cu) or an alloy of copper (Cu), and the ball may include a low-melting point metal, for example, tin (Sn) or an alloy including tin (Sn) (Sn—Ag—Cu). According to some embodiments, the external connection bumps 360 may include only the pillar or the ball. According to some embodiments, a resist layer (not illustrated) may be formed on a lower surface of the lower redistribution structure 310 to protect the external connection bumps 360 from physical and chemical damage.

The plurality of posts 320 may penetrate the encapsulant 330 to electrically connect the lower redistribution layer 312 and the upper connection bumps 250. The plurality of posts 320 may include copper (Cu), nickel (Ni), titanium (Ti), lead (Pb), aluminum (Al), silver (Ag), gold (Au), platinum (Pt), or alloys thereof. The plurality of posts 320 may extend in the vertical direction (Z-direction) in the encapsulant 330. The plurality of posts 320 may have a cylindrical shape, but the present inventive concept is not limited thereto.

The plurality of posts 320 may be disposed asymmetrically around the lower chip structure 100. The plurality of posts 320 may be disposed more in a region overlapping the upper chip structure 200. At least some posts 320 among the plurality of posts 320 may be disposed in a region opposite to (or horizontally offset from) the upper chip structure 200, based on the heat dissipation member 350. For example, the number of the plurality of posts 320 overlapping the upper chip structure 200 in the vertical direction (Z-direction) may be greater than the number of at least some of the posts 320 in a region opposite to the upper chip structure 200, based on the heat dissipation member 350.

The encapsulant 330 may cover at least some of each of the lower chip structure 100 and the plurality of posts 320. The encapsulant 330 may cover or surround a side surface of each of the lower chip structure 100 and the plurality of posts 320. The encapsulant 330 may expose an upper surface of each of the plurality of posts 320. According to some embodiments, the encapsulant 330 may expose an upper surface of the lower chip structure 100 and an upper surface of the adhesive layer 140. An upper surface of the encapsulant 330 may be coplanar or substantially coplanar with the upper surface of the adhesive layer 140 and the upper surfaces of the plurality of posts 320. The encapsulant 330 may include, for example, a thermosetting resin such as an epoxy resin, a thermoplastic resin such as a polyimide, or a prepreg, an ABF, an FR-4, BT, an epoxy molding compound (EMC). For example, the encapsulant 330 may include an EMC.

The upper encapsulating layer 120 may be disposed on the encapsulant 330, may include an insulating material, and may include a laser debonding layer for separating the carrier substrate 10 and the lower package structure LS during a process.

The laser debonding layer may include a photoimageable dielectric (PID) or photosensitive resin compositions, and polymer bonding of a joining surface with the carrier substrate 10 may be variable by a laser, to debond the carrier substrate 10 and the lower package structure LS. For example, the laser debonding layer may include a polymer material having an absorption rate of 50% or more, preferably 60% or more, of a laser having a wavelength of UV, specifically, 308 nm, 343 nm, or 355 nm. For example, the laser debonding layer may include at least one of polybenzoxazole (PBO), polyimide (PI), or a phenol-based resin. In addition, the laser debonding layer may be formed of only a polymer resin without a separate filler, the polymer resin may be slit coated or spin coated on the carrier substrate 10, and may be cured to form the upper encapsulating layer 120 having the second thickness t2.

The upper encapsulating layer 120 may be shorter than a length of the post 320, and when the length of the post 320 is 150 to 200 μm, the second thickness t2 of the upper encapsulating layer 120 may be 15 μm to 20 μm.

The upper connection bumps 250 may be disposed in the upper encapsulating layer 120, to be aligned with the posts 320 in the Z-direction and to connect the second connection terminals 212 of the upper chip structure 200. The upper connection bumps 250 may penetrate the upper encapsulating layer 120, may extend vertically, may have a width decreasing from an upper surface to a lower surface, and may have an inclined side surface. The upper connection bumps 250 may include a metal material including, for example, copper (Cu), aluminum (Al), silver (Ag), tin (Sn), gold (Au), nickel (Ni), lead (Pb), titanium (Ti), or alloys thereof.

The heat dissipation member 350 may be disposed on one side of the upper encapsulating layer 120 to overlap the lower chip structure 100 vertically (in the Z-direction). The heat dissipation member 350 may control warpage of the semiconductor package 300 and may discharge heat generated by the lower chip structure 100 externally. The heat dissipation member 350 may include a material having excellent thermal conductivity, such as aluminum (Al), gold (Au), silver (Ag), copper (Cu), iron (Fe), graphite, graphene, or the like.

The heat dissipation member 350 may have an area (e.g., planar area), equal to or larger than an area of the lower chip structure 100 of the lower package structure LS, and may be disposed to overlap the lower chip structure 100 in the Z-direction, to completely cover or overlie an upper surface of the lower chip structure 100.

Therefore, when the heat dissipation member 350 has an area, larger than an area of the lower chip structure 100, it may be disposed to protrude outward by a first distance d1 from a side surface of the lower chip structure 100. The heat dissipation member 350 may be located in the lower package structure LS even when protruding outwardly by the first distance d1, and one side surface of the heat dissipation member 350 may be horizontally offset from a side surface of the lower package structure LS, but alternatively, the heat dissipation member 350 may have a side surface, parallel to one side surface of the lower package structure LS.

A heat transfer material layer 355 may be located between the heat dissipation member 350 and the lower chip structure 100. The heat transfer material layer 355 may penetrate the upper encapsulating layer 120 of the lower package structure LS, may penetrate the adhesive layer 140 on the lower chip structure 100, and may be in direct contact with an upper surface of the lower chip structure 100. The heat transfer material layer 355 may be in direct contact with the heat dissipation member 350 and the lower chip structure 100 without any other member therebetween, to attach the two structures to each other. The heat transfer material layer 355 may include, for example, a thermal interface material (TIM) such as a thermally conductive adhesive tape, a thermally conductive grease, a thermally conductive adhesive, or the like.

The heat transfer material layer 355 may have an area (e.g., planar area), smaller than an area of the heat transfer material 350, to be disposed inwardly of a side surface of the heat transfer material 350 and a side surface of the lower package structure LS. Specifically, when viewed in a planar manner, the heat transfer material layer 355 may be located in a planar area of the heat transfer material 350. For example, an upper surface of the heat transfer material layer 355 may be disposed to be in direct contact with a lower surface of the heat transfer material 350 and to have an area, smaller than an area of the lower surface of the heat transfer material 350. A lower surface of the heat transfer material layer 355 may be disposed to be in direct contact with an upper surface of the lower chip structure 100 and to have an area, smaller than an area of the upper surface of the lower chip structure 100. The heat transfer material layer 355 may have a width decreasing from the upper surface to the lower surface, and may have an inclined side surface. The area of the upper surface of the heat transfer material layer 355 may be smaller than the area of the upper surface of the lower chip structure 100. For example, as illustrated in FIG. 3, the outer edge of the upper surface of the heat transfer material layer 355 may be disposed inwardly to be spaced apart from the outer edge of the upper surface of the lower chip structure 100 by a second distance d2, the outer edge of the lower surface of the heat transfer material layer 355 may be disposed inwardly to be spaced apart from the outer edge of the upper surface of the lower chip structure 100 by a third distance d3, and the heat transfer material layer 355 may have the inclined side surface such that the third distance d3 is greater than the second distance d2.

The heat transfer material layer 355 may penetrate each of the upper encapsulating layer 120 and the adhesive layer 140 to extend from the lower surface of the heat dissipation member 350 to the upper surface of the lower chip structure 100, and the side surface of the heat transfer material layer 355 may have a continuous slope without a bend, but the present inventive concept is not limited thereto. A third thickness t3 of the heat transfer material layer 355 may be equal to a sum of the second thickness t2 of the upper encapsulating layer 120 and the first thickness t1 of the adhesive layer 140. The third thickness t3 of the heat transfer material layer 355 may be greater than a vertical length or thickness of the upper connection bumps 250.

Therefore, an upper edge n1 and a lower edge n2 of the internal side surface Sb of the adhesive layer 140 may form different junction points. Specifically, the upper edge n1 may be in simultaneous contact with the heat transfer material layer 355, the upper encapsulating layer 120, and the adhesive layer 140, and the lower edge n2 may be in simultaneous contact with the heat transfer material layer 355, the adhesive layer 140, and a portion (e.g., a sealing material) of the lower chip structure 100.

FIGS. 4A and 4B are cross-sectional views illustrating example embodiments of a lower chip structure 100 applicable to the semiconductor package 300 of FIG. 1, and FIG. 4C is a cross-sectional view illustrating example embodiments of an upper chip structure 200 applicable to the semiconductor package 300 of FIG. 1.

Referring to FIG. 4A, a lower chip structure 100A of example embodiments may include a plurality of semiconductor chips 100a and 100b vertically (Z-direction) stacked. At least some of the plurality of semiconductor chips 100a and 100b (e.g., ‘100a’) may include through-vias 130 electrically connecting the plurality of semiconductor chips 100a and 100b to each other. The plurality of semiconductor chips 100a and 100b may be chiplets forming a multi-chip module (MCM). The plurality of semiconductor chips 100a and 100b may include a central processor (CPU), a graphics processor (GPU), a field programmable gate array (FPGA), a digital signal processor (DSP), an encryption processor, a microprocessor, a microcontroller, an analog-to-digital converter, an application-specific integrated circuit (ASIC), a volatile memory, a non-volatile memory, an input/output (I/O) circuit, an analog circuit, a serial-to-parallel conversion circuit, or the like.

The lower chip structure 100A may include a first semiconductor chip 100a and a second semiconductor chip 100b, and the first semiconductor chip 100a may include a processor circuit, and the second semiconductor chip 100b may include at least one of an input/output circuit, an analog circuit, a memory circuit, or a serial-to-parallel conversion circuit for the processor circuit. The plurality of semiconductor chips 100a and 100b may be provided in a greater number than that illustrated in the drawing. According to some embodiments, the lower chip structure 100A may further include a molding member 142 covering or surrounding at least a portion of each of the first semiconductor chip 100a and the second semiconductor chip 100b. According to some embodiments, an underfill or underfill portion 141 may be formed between the first semiconductor chip 100a and the second semiconductor chip 100b.

The first semiconductor chip 100a and/or the second semiconductor chip 100b may include a substrate 101, an upper protective layer 103, an upper pad 105, a circuit layer 110, a lower pad 104, and/or a through-via 130. The substrate 101 may include, for example, a semiconductor element such as silicon or germanium (Ge), or may include a compound semiconductor such as silicon carbide (SiC), gallium arsenide (GaAs), indium arsenide (InAs), or indium phosphide (InP). The substrate 101 may have a silicon-on-insulator (SOI) structure. The substrate 101 may have a conductive region, for example, a well doped with impurities, or an active surface doped with impurities and an inactive surface opposite thereto. The substrate 101 may include various device isolation structures such as a shallow trench isolation (STI) structure.

The upper protective layer 103 may be formed on the inactive surface of the substrate 101 and may protect the substrate 101. The upper protective layer 103 may be formed as an insulating layer such as a silicon oxide film, a silicon nitride film, a silicon oxynitride film, or the like, but a material of the upper protective layer 103 is not limited to the above materials. For example, the upper protective layer 103 may be formed of a polymer such as polyimide (PI). Although not illustrated in the drawing, a lower protective layer may be further formed on a lower surface of the circuit layer 110.

The upper pad 105 may be disposed on or in the upper protective layer 103. The upper pad 105 may include, for example, at least one of aluminum (Al), copper (Cu), nickel (Ni), tungsten (W), platinum (Pt), or gold (Au). The lower pad 104 may be disposed on or in a lower portion of the circuit layer 110, and may include a material similar to that of the upper pad 105. However, a material of the upper pad 105 and a material of the lower pad 104 are not limited to the above materials.

The circuit layer 110 may be disposed on the active surface of the substrate 101 and may include various types of devices. For example, the circuit layer 110 may include an FET such as a planar field effect transistor (FET), a FinFET, or the like, a memory element such as a flash memory, a dynamic random access memory (DRAM), a static random access memory (SRAM), an electrically erasable programmable read-only memory (EEPROM), a phase-change random access memory (PRAM), a magnetoresistive random access memory (MRAM), a ferroelectric random access memory (FeRAM), a resistive random access memory (RRAM), a logic element such as an AND, an OR, a NOT, or the like, various active devices such as a system large scale integration (LSI), a CMOS imaging sensors (CIS), a micro-electro-mechanical system (MEMS), and/or a passive device. The circuit layer 110 may include a wiring structure electrically connected to the above-described elements, and an interlayer insulating layer surrounding the wiring structure. The interlayer insulating layer may include silicon oxide or silicon nitride. The wiring structure may include a multilayer wiring and/or a vertical contact. The wiring structure may connect elements of the circuit layer 110 to each other, may connect elements to a conductive region of the substrate 101, or may connect elements to the through-vias 130.

The through-vias 130 may penetrate the substrate 101 in the vertical direction (Z-direction) and may provide an electrical path connecting the upper pads 105 and the lower pads 104. The through-vias 130 may include a conductive plug and a barrier film surrounding the conductive plug. The conductive plug may include a metal, for example, tungsten (W), titanium (Ti), aluminum (Al), or copper (Cu). The conductive plug may be formed by a plating process, a PVD process, or a CVD process. The barrier film may include an insulating barrier film and/or a conductive barrier film. The insulating barrier film may be formed of an oxide, a nitride, a carbide, a polymer, or a combination thereof. The conductive barrier film may be disposed between the insulating barrier film and the conductive plug. The conductive barrier film may include a metal compound, such as tungsten nitride (WN), titanium nitride (TiN), or tantalum nitride (TaN), for example. The barrier film may be formed by a PVD process or a CVD process.

Connection bumps 150 may be disposed between the first semiconductor chip 100a and the second semiconductor chip 100b. The connection bumps 150 may have a form in which a pillar (or underbump metal) and a ball are combined. The pillar may include copper (Cu) or an alloy of copper (Cu), and the ball may include a low-melting point metal, for example, tin (Sn) or an alloy including tin (Sn) (Sn—Ag—Cu). According to some embodiments, the connection bumps 150 may have a form consisting of only the pillar or the ball. Lower connection bumps 106 may be disposed below the first semiconductor chip 100a. The lower connection bumps 106 may be connected to the lower pads 104 and may be physically and electrically connected to lower redistribution structures 310. The lower connection bumps 106 may have a pillar (or underbump metal) form. The pillar may include copper (Cu) or an alloy of copper (Cu).

Referring to FIG. 4B, a lower chip structure 100B of example embodiments may include a plurality of semiconductor chips 100a and 100b directly joined and coupled without a separate connecting member (e.g., solder bump, copper post, or the like). The lower chip structure 100B may include a bonding surface BS in which an upper surface of a first semiconductor chip 100a and a lower surface of a second semiconductor chip 100b are joined. The bonding surface BS may be formed by metal bonding and dielectric bonding. For example, an upper protective layer 103 of the first semiconductor chip 100a and a circuit layer 110 of the second semiconductor chip 100b, forming the bonding surface BS, may include a material that may be joined and coupled to each other, such as at least one of silicon oxide (SiO), silicon nitride (SiN), or silicon carbonitride (SiCN).

Referring to FIG. 4C, an upper chip structure 200A of example embodiments may include a substrate 210, a plurality of semiconductor chips 200a, 200b, and 200c, and a molding member 230.

The substrate 210 may be a support substrate on which the plurality of semiconductor chips 200a, 200b, and 200c are mounted, and may include a printed circuit board (PCB), a ceramic substrate, a glass substrate, a tape wiring substrate, or the like. The substrate 210 may include a lower pad 212 and an upper pad 211 on a lower surface and an upper surface thereof, respectively, which may be electrically connected to the outside. In addition, the substrate 210 may include an interconnection circuit 213 electrically connecting the lower pad 212 and the upper pad 211.

The plurality of semiconductor chips 200a, 200b, and 200c may be mounted on the substrate 210 by wire bonding or flip-chip bonding. For example, the plurality of semiconductor chips 200a, 200b, and 200c may be stacked vertically (in the Z-direction) on the substrate 210 and may be electrically connected to the upper pad 211 of the substrate 210 by a bonding wire WB. The plurality of semiconductor chips 200a, 200b, and 200c may include a volatile memory chip and/or a non-volatile memory chip.

The molding member 230 may cover or surround at least a portion of the plurality of semiconductor chips 200a, 200b, and 200c on the substrate 210. The molding member 230 may include a material identical to or similar to the encapsulant 330 described above. Below the substrate 210, the lower pad 212 for connection with upper connection bumps 250 may be exposed.

The lower chip structures 100A and 100B and the upper chip structure 200A, described above with reference to FIGS. 4A to 4C, are illustrative, and shapes of a lower chip structure 100 and an upper chip structure 200, applicable to a semiconductor package according to the present inventive concept, are not limited thereto.

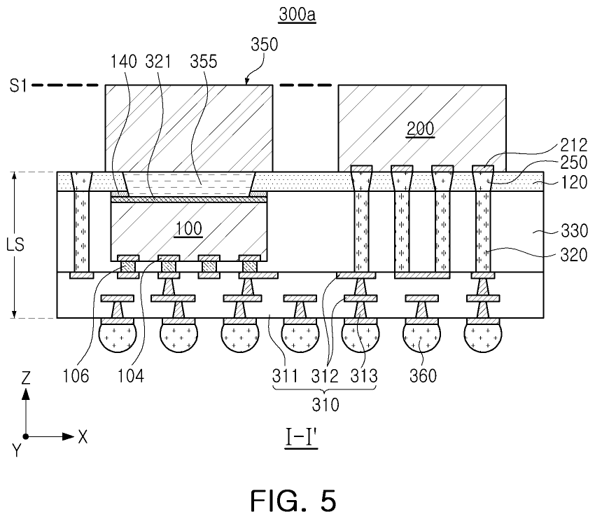

Hereinafter, with reference to FIGS. 5 to 10, a semiconductor package according to various embodiments will be described.

Referring to FIG. 5, a semiconductor package 300a of example embodiments may further include a laser blocking layer 321. Specifically, the semiconductor package 300a may further include the laser blocking layer 321 on an upper surface of a lower chip structure 100. The laser blocking layer 321 may include copper (Cu), nickel (Ni), titanium (Ti), lead (Pb), aluminum (Al), silver (Ag), gold (Au), platinum (Pt), or alloys thereof. The laser blocking layer 321 may have an area (e.g., planar area), equal to an area of the lower chip structure 100, and an adhesive layer 140 may be disposed in a frame shape on an edge region of an upper surface of the laser blocking layer 321.

A heat transfer material layer 355 may be disposed on the laser blocking layer 321 to contact an internal side surface Sb of the frame-shaped adhesive layer 140. Therefore, a lower edge n2 of the internal side surface Sb of the adhesive layer 140 (see e.g., the lower edge n2 and the internal side surface Sb in FIG. 3) may be joined to the adhesive layer 140, the heat transfer material layer 355, and the laser blocking layer 321. The laser blocking layer 321 may block a laser in a laser cavity forming process for arranging the heat transfer material layer 355, to protect the lower chip structure 100 therebelow.

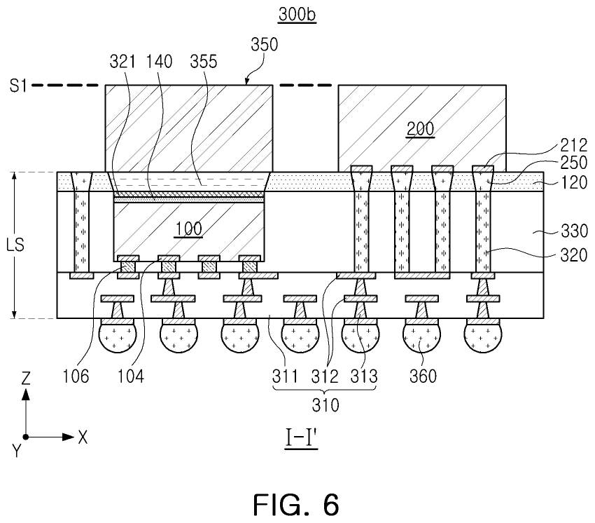

Referring to FIG. 6, in a semiconductor package 300b of example embodiments, a laser blocking layer 321 may be disposed on an adhesive layer 140, and the adhesive layer 140 may be disposed in a plate shape, instead of a frame shape. Specifically, the semiconductor package 300b may be disposed such that the adhesive layer 140 may be disposed in a plate shape on an upper surface of a lower chip structure 100, and may have an area (e.g., planar area), equal to an area of the upper surface of the lower chip structure 100. A laser blocking layer 321 may be disposed on an upper surface of the adhesive layer 140. The laser blocking layer 321 may be disposed to have an area (e.g., planar area), equal to an area of the adhesive layer 140, and to align a side surface from the laser blocking layer 321 to the lower chip structure 100 in the Z-direction. An upper surface of the laser blocking layer 321 may be disposed to be coplanar with an upper surface of an encapsulant 330, and the upper surface of the laser blocking layer 321 and a lower surface of a heat transfer material layer 355 may be in direct contact with each other. Therefore, a thickness of the heat transfer material layer 355 may be equal to a thickness of an upper encapsulating layer 120, and the heat transfer material layer 355 may not protrude into the laser blocking layer 321.

The laser blocking layer 321 may include copper (Cu), nickel (Ni), titanium (Ti), lead (Pb), aluminum (Al), silver (Ag), gold (Au), platinum (Pt), or alloys thereof. The laser blocking layer 321 may block a laser in a laser cavity forming process for arranging the heat transfer material layer 355, to protect the lower chip structure 100 below, and as a portion of a seed layer 301 for forming posts 320, may include the same material as the posts 320, but the present inventive concept is not limited thereto.

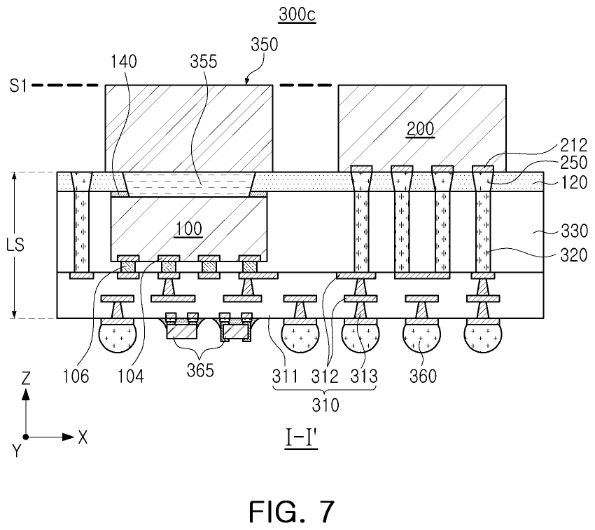

Referring to FIG. 7, in a semiconductor package 300c of example embodiments, at least one passive device 365 may be disposed below a lower redistribution structure 310. The passive device 365 may include, for example, a capacitor, an inductor, beads, or the like. The passive component 365 may be flip-chip bonded to a lower surface of the lower redistribution structure 310. The passive component 365 may be electrically connected to a lower redistribution layer 312 through a solder bump or the like. An underfill resin may be filled between the passive component 365 and the lower redistribution structure 310.

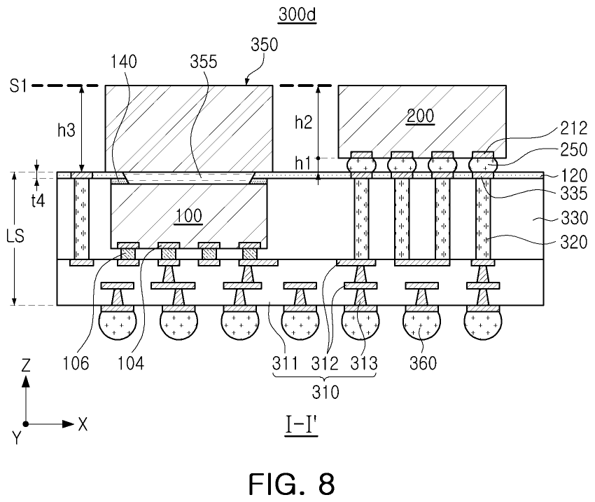

Referring to FIG. 8, in a semiconductor package 300d of example embodiments, a fourth thickness t4 of an upper encapsulating layer 120 may be equal to or smaller than a first thickness t1 of an adhesive layer 140 therebelow.

Specifically, the upper encapsulating layer 120 may have the very thin fourth thickness t4, unlike the semiconductor package 300 of FIG. 2. The upper encapsulating layer 120 may be formed very thinly, and upper interconnection layers 335 penetrating through the upper encapsulating layer 120 and physically and electrically connected to posts 320 may be further disposed. The upper interconnection layers 335 may be prepared by forming openings in the upper encapsulating layer 120 exposing upper surfaces of the posts 320 below and filling the openings with a conductive material. Upper connection bumps 250 may be further disposed on the upper interconnection layers 335 connected to the posts 320 and connected to lower pads 212 of an upper chip structure 200. The upper connection bumps 250 may include a low-melting point metal, for example, tin (Sn) or an alloy including tin (Sn) (e.g., Sn—Ag—Cu) and may be disposed to have a first height or thickness h1. When the upper chip structure 200 has a second height or thickness h2 above the upper connection bumps 250 of the first height h1, a heat dissipation member 350 may have a third height or thickness h3, equal to a sum of the first height h1 and the second height h2. Therefore, an upper surface of a heat dissipation member 350 and an upper surface of the upper chip structure 200 may have a common (e.g., coplanar) surface S1, but the present inventive concept is not limited thereto.

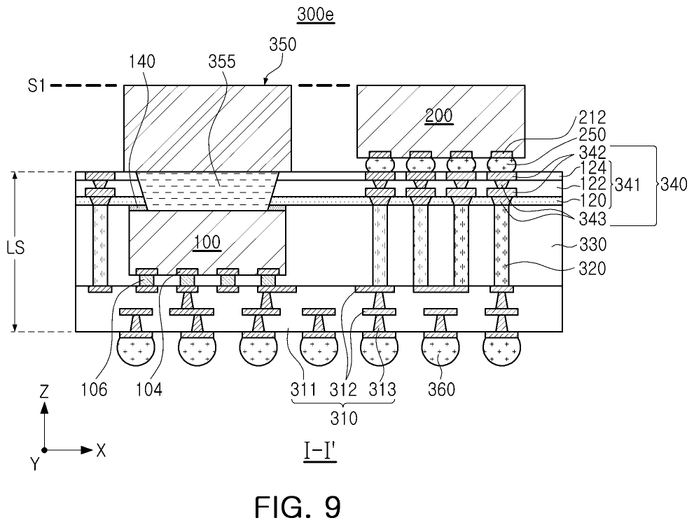

Referring to FIG. 9, in a semiconductor package 300e of example embodiments, an upper redistribution structure 340 may be further included on a lower semiconductor structure LS. The upper redistribution structure 340 may include an upper insulating layer 341, upper redistribution layers 342, and an upper redistribution via 343. The upper redistribution structure 340 may electrically connect at least some of posts 320 to an upper chip structure 200.

The upper insulating layer 341 may be a stacked structure of a plurality of insulating layers 120, 122, and 124, and may include a first insulating layer 120 and at least one layer of second insulating layers 122 and 124 on the first insulating layer 120. The first insulating layer 120 may include a laser debonding layer.

The laser debonding layer may include a photoimageable dielectric (PID) or photosensitive resin compositions, and bonding of a joining surface with a carrier substrate 10 may be variable by a laser, to debond the carrier substrate 10 and the lower package structure LS. Specifically, the first insulating layer 120 may include a polymer material having an absorption rate of 50% or more, preferably 60% or more, of a laser having a wavelength of 308 nm, 343 nm, or 355 nm. As an example, the first insulating layer 120 may include at least one of polybenzoxazole (PBO), polyimide (PI), or a phenol-based resin. In addition, the laser debonding layer may be formed of only a polymer resin without a separate filler and may be formed by slitting or spin-coating and curing the polymer resin on the carrier substrate.

At least one layer of the second insulating layers 122 and 124 may be disposed on the first insulating layer 120, and the second insulating layers 122 and 124 may include a different material from the first insulating layer 120, but the present inventive concept is not limited thereto. The second insulating layers 122 and 124 may include a thermosetting resin such as an epoxy resin, a thermoplastic resin such as a polyimide, or a resin in which an inorganic filler is impregnated thereinto, such as a prepreg, an Ajinomoto build-up film (ABF), an FR-4, or bismaleimide-triazine (BT).

A layer structure of the second insulating layers 122 and 124 may be changed according to a circuit design of an upper redistribution layer 342, and a boundary between the plurality of insulating layers 120, 122, and 124 may be unclear depending on a process.

The upper redistribution layer 342 may be disposed on or in the upper insulating layer 341 and may redistribute the second connection terminal 212 of the upper chip structure 200. The upper redistribution layer 342 may include a metal, for example, copper (Cu), aluminum (Al), silver (Ag), tin (Sn), gold (Au), nickel (Ni), lead (Pb), titanium (Ti), or alloys thereof. The upper redistribution layer 342 may perform various functions depending on a design. The upper redistribution layer 342 may include more or fewer redistribution layers than those illustrated in the drawing.

The upper redistribution via 343 may extend vertically within the upper insulating layer 341 and may be electrically connected to the upper redistribution layer 342. For example, the upper redistribution via 343 may interconnect the upper redistribution layers 342 on different levels. The upper redistribution via 343 may include a metal material, for example, copper (Cu), aluminum (Al), silver (Ag), tin (Sn), gold (Au), nickel (Ni), lead (Pb), titanium (Ti), or alloys thereof. The upper redistribution via 343 may be a filled via in which a metal material is filled inside a via hole or may be a conformal via in which a metal material extends along an inner wall of a via hole.

Upper connection bumps 250 may be disposed between the upper redistribution layer 342 and a second connection terminal 212 of the upper chip structure 200, and the upper connection bumps 250 may be implemented as ball-type bumps of FIG. 8, but the present inventive concept is not limited thereto.

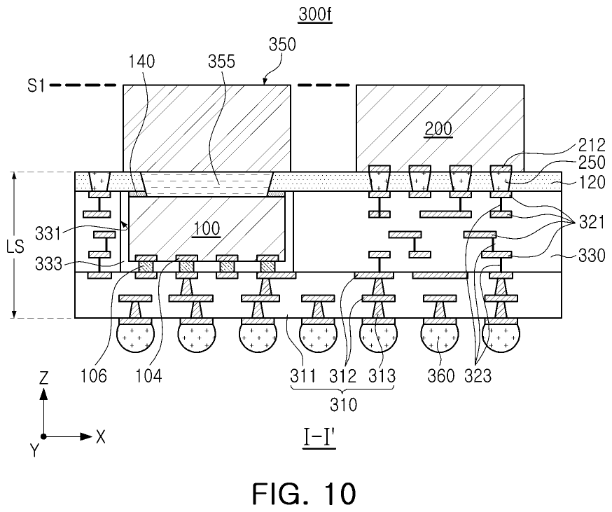

Referring to FIG. 10, in a semiconductor package 300f of example embodiments, a lower semiconductor structure LS may further include redistribution layers 321 for connecting a lower redistribution structure 310 and an upper connection bump 250 inside an encapsulant 330. The redistribution layers 321 may include a layer structure of at least two layers and may also include a layer structure of four layers as in FIG. 10. Vias 323 connecting the redistribution layers 321 of each of the layers may be disposed. The vias 323 may perform the same function as the posts 320 of FIG. 2 by connecting upper and lower portions of the redistribution layers 321 to each other. The encapsulant 330 may be disposed including a plurality of insulating layers.

The encapsulant 330 may include a cavity 331 for accommodating a lower chip structure 100 therein, and the lower chip structure 100 may be disposed inside the cavity 331. The cavity 331 may have an area (e.g., planar area), larger than an area of the lower chip structure 100 such that the lower chip structure 100 may be settled inside the cavity 331, but the present inventive concept is not limited thereto. A sealing member 333 may be further disposed in a space between the cavity 331 and the lower chip structure 100.

FIGS. 11A to 11J are cross-sectional views illustrating a process of manufacturing a semiconductor package according to example embodiments.

Referring to FIG. 11A, a laser debonding layer 120 may be formed on a carrier substrate 10.

The carrier substrate 10 may be a temporary support in a form of a wafer or a panel. The carrier substrate 10 may be a glass substrate, but the present inventive concept is not limited thereto, and may include a light-transmitting resin material.

The laser debonding layer 120 may include a photoimageable dielectric (PID) or a photosensitive resin composition and may include a polymer material having an absorption rate of 50% or more, preferably 60% or more, of a laser having a wavelength of UV, e.g., a wavelength of 308 nm, 343 nm, or 355 nm. For example, the laser debonding layer 120 may include at least one of polybenzoxazole (PBO), polyimide (PI), or a phenol-based resin. In addition, the laser debonding layer 120 may be formed of only a polymer resin without a separate filler, the polymer resin may be slit coated or spin coated on the carrier substrate 10, and may be cured to form the laser debonding layer 120 having a second thickness t2.

Referring to FIG. 11B, a seed layer 301 may be formed on the laser debonding layer 120.

The seed layer 301 may include at least one metal layer, and as the seed layer 301 for forming a post 320, a titanium (Ti) layer may be formed as a first layer, and a copper (Cu) layer may be further formed as a second layer on the titanium layer.

The first layer may have a thickness of 50 to 100 μm, preferably 80 μm, and the second layer may have a thickness of 150 to 250 μm, preferably 200 μm, but the present inventive concept is not limited thereto. The seed layer 301 may be formed only with the titanium layer, or alternatively, the seed layer 301 may be formed only with the copper layer.

Referring to FIG. 11C, a photoresist PR may be applied on the seed layer 301, a photo process may be performed to expose a region in which the posts 320 are to be formed, and the exposed region may be plated onto the seed layer 301 therebelow to form preliminary posts 320P.

A plurality of preliminary posts 320P may be formed by plating with copper (Cu), nickel (Ni), titanium (Ti), lead (Pb), aluminum (Al), silver (Ag), gold (Au), platinum (Pt), or alloys thereof.

Referring to FIG. 11D, the photoresist PR may be removed, and the seed layer 301, other than the preliminary posts 320P, may be removed to expose only the preliminary posts 320P.

In this case, the seed layer 301 may remain below the preliminary posts 320P, and when the seed layer 301 and a plating layer include the same material, they may be formed without a layer structure, but when the seed layer 301 may include a different material from the plating layer, the preliminary posts 320P including the layer structure may be formed.

When a laser blocking layer 321 is formed as the seed layer 301, as in FIG. 6, the seed layer 301 may be maintained without being etched in a region in which a lower chip structure 100 is to be formed.

Referring to FIG. 11E, a lower chip structure 100 may be mounted on the laser debonding layer 120. The lower chip structure 100 may be mounted to be inverted upside down such that an adhesive layer 140 and the laser debonding layer 120 are in contact with each other, in a state in which the adhesive layer 140 is disposed on an upper surface.

A plurality of preliminary lower connection bumps 106P and a plurality of solder balls 107P may be formed on a lower surface of the lower chip structure 100. The solder balls 107P may be respectively disposed on a lower end of the preliminary lower connection bumps 106P, but may be mounted in a state in which only the preliminary lower connection bumps 106P are connected without the solder balls 107P. The lower chip structure 100 may be mounted on the laser debonding layer 120 in an inverted state such that the preliminary lower connection bumps 106P on a lower surface of the lower chip structure 100 are exposed upward. For such die bonding, the adhesive layer 140 may be disposed between the laser debonding layer 120 and the lower chip structure 100, and the lower chip structure 100 may be fixed through thermal compression.

Referring to FIG. 11F, an encapsulant 330 may be formed.

The encapsulant 330 may be applied to cover the lower chip structure 100 and the plurality of preliminary posts 320P. The encapsulant 330 may be formed, for example, by applying and curing an EMC. A planarization process may be performed such that the preliminary lower connection bumps 106P and the preliminary posts 320P have the same upper surface (e.g., coplanar). The planarization process may include a grinding process, a chemical mechanical polishing (CMP) process, or the like. Through the planarization process, the solder balls 107P on the preliminary lower connection bumps 106P may be removed, and a first level 11, which may be a level of a lower surface of the preliminary lower connection bumps 106P, may be reduced to a second level 12. In addition, an initial level 10, which may be a level of a lower surface of the preliminary posts 320P, may be reduced to the second level 12. The second level 12 may be a level, coplanar with the encapsulant 330, lower connection bumps 106, and posts 320.

Referring to FIG. 11G, a lower redistribution structure 310 may be formed on the planarized encapsulant 330.

The lower redistribution structures 310 may be formed on a wafer level or a panel level. The lower redistribution structure 310 may include a lower insulating layer 311, a lower redistribution layer 312, and a lower redistribution via 313. The lower insulating layer 311 may be formed by sequentially applying and curing a photosensitive material, for example, PID. The lower redistribution layer 312 and the lower redistribution via 313 may be formed by performing an exposure process and a development process to form a via hole penetrating through the lower insulating layer 311 and patterning a metal material on the lower insulating layer 311 using a plating process. A redistribution pad 312 may be formed on an upper surface of the lower redistribution structure 310.

As illustrated in FIG. 11H, the carrier substrate 10 may be separated from a lower semiconductor structure LS.

The lower semiconductor structure LS may be flipped upside down such that the carrier substrate 10 may be exposed upward, and a UV laser, for example, a laser having a wavelength of 308 nm, 343 nm, or 355 nm, may be irradiated to induce a change in surface properties of the laser debonding layer 120, to separate the carrier substrate 10.

Specifically, the laser debonding layer 120, including a photosensitive material, may undergo a polymerization reaction in which carbon particles of polymer materials on a surface are combined with neighboring carbon particles by the UV laser provided through the carrier substrate 10 to emit carbon dioxide (CO₂) or carbon monoxide (CO). Such a polymerization reaction may occur on a surface of the laser debonding layer 120 contacting the carrier substrate 10, and, at the same time, particles that increase in size may be generated on the surface. By such large particles, the carrier substrate 10 and the laser debonding layer 120 may be debonded to complete the lower semiconductor structure LS maintaining the laser debonding layer 120 as an upper encapsulating layer 120 on an upper surface.

As illustrated in FIG. 11I, a cavity OP1 exposing an upper surface of the lower chip structure 100 and openings OP2 exposing an upper surface of the posts 320 may be formed on the upper encapsulating layer 120, which may be the laser debonding layer, through a laser cavity process.

The cavity OP1 may simultaneously remove the laser debonding layer 120 and the adhesive layer 140, and the cavity OP1 having a side surface with a continuous slope may be formed.

Referring to FIG. 11J, a heat transfer material layer 355 may be disposed inside the cavity OP1. The heat transfer material layer 355 may include a thermal interface material (TIM) of a gel type, a pad type, or a film type. In addition, upper connection bumps 250 may be formed within the openings OP2.

Next, as illustrated in FIG. 2, an upper chip structure 200 and a heat dissipation member 350 may be disposed.

The upper chip structure 200 may be electrically connected to the upper redistribution layer 342 through the upper connection bumps 250. The heat dissipation member 350 may be disposed on the heat transfer material layer 355 and may be disposed to be vertically aligned with the lower chip structure 100.

Since the heat transfer material layer 355 may be disposed only within a region of the heat dissipation member 350, occurrence of burrs may be reduced. In addition, since no other material layer is disposed between the heat dissipation member 350, the heat transfer material layer 355, and the lower chip structure 100, heat dissipation efficiency may be improved.

According to embodiments, a carrier substrate and a separation layer of a semiconductor package may be applied as an insulating layer, and, at the same time, a portion of the separation layer may be removed to dispose a heat transfer material layer joining a heat dissipation member and a lower chip structure, to increase heat transfer efficiency by direct joining, and to improve reliability. In addition, since an additional insulating layer may not be disposed on a lower semiconductor chip to increase a thickness of the heat dissipation member, heat dissipation efficiency may be improved.

Various advantages and effects of the present inventive concept are not limited to the above-described contents and will be more easily understood in the process of explaining example embodiments herein.

While example embodiments have been illustrated and described above, it will be apparent to those skilled in the art that modifications and variations could be made without departing from the scope of the present inventive concept as defined by the appended claims.

1. A semiconductor package comprising:
a lower redistribution structure including a lower redistribution layer;
external connection bumps below the lower redistribution structure and electrically connected to the lower redistribution layer;
a lower chip structure on the lower redistribution structure and electrically connected to the lower redistribution layer;
an encapsulant at least partially encapsulating the lower chip structure;
an upper encapsulating layer on the encapsulant;
an adhesive layer on an upper surface of the lower chip structure and fixing the lower chip structure to the upper encapsulating layer;
a plurality of posts extending through the encapsulant and electrically connected to the lower redistribution layer;
an upper chip structure on the upper encapsulating layer and electrically connected to the plurality of posts;
a heat dissipation member on one side of the upper chip structure and overlapping the lower chip structure in a vertical direction; and
a heat transfer material layer extending through the upper encapsulating layer and the adhesive layer and disposed between the heat dissipation member and the lower chip structure.

2. The semiconductor package of claim 1, wherein the adhesive layer has a frame shape on the upper surface of the lower chip structure.

3. The semiconductor package of claim 2, wherein the adhesive layer comprises an upper surface directly joined to a lower surface of the upper encapsulating layer, a lower surface directly joined to the upper surface of the lower chip structure, an external side surface exposed externally between the upper surface of the adhesive layer and the lower surface of the adhesive layer, and an internal side surface exposed inside of the frame shape between the upper surface of the adhesive layer and the lower surface of the adhesive layer, and
the internal side surface has an incline from the upper surface of the adhesive layer to the lower surface of the adhesive layer.

4. The semiconductor package of claim 3, wherein the heat transfer material layer, the adhesive layer, and the upper encapsulating layer are in contact with each other on an upper edge of the internal side surface of the adhesive layer.

5. The semiconductor package of claim 1, wherein the heat transfer material layer includes an upper surface directly joined to a lower surface of the heat dissipation member, a lower surface directly joined to the upper surface of the lower chip structure, and a side surface continuously sloped between the upper surface of the heat transfer material layer and the lower surface of the heat transfer material layer.

6. The semiconductor package of claim 5, wherein an area of the upper surface of the heat transfer material layer is larger than an area of the lower surface of the heat transfer material layer.

7. The semiconductor package of claim 1, wherein, in plan view, the heat transfer material layer is within a planar area of the heat dissipation member and within a planar area of the lower chip structure.

8. The semiconductor package of claim 1, further comprising upper connection bumps extending through the upper encapsulating layer and electrically connecting the plurality of posts and the upper chip structure.

9. The semiconductor package of claim 8, wherein a thickness of the heat transfer material layer is greater than a vertical length of each of the upper connection bumps.

10. The semiconductor package of claim 1, further comprising a laser blocking layer on the upper surface of the lower chip structure.

11. The semiconductor package of claim 10, wherein the laser blocking layer comprises the same material as the plurality of posts.

12. The semiconductor package of claim 1, further comprising ball-shaped upper connection bumps electrically connecting the plurality of posts and the upper chip structure on the upper encapsulating layer.

13. The semiconductor package of claim 1, wherein a vertical level of an upper surface of the heat dissipation member is the same as a vertical level of an upper surface of the upper chip structure.

14. The semiconductor package of claim 1, wherein the lower chip structure comprises at least one logic chip, and
the upper chip structure comprises at least one memory chip.

15. A semiconductor package comprising:
a lower package structure including a lower chip structure, an adhesive layer on the lower chip structure, and an upper encapsulating layer on the adhesive layer and including a photosensitive resin composition;
a heat dissipation member on the lower package structure and overlapping the lower chip structure in a vertical direction;
an upper chip structure on the lower package structure and spaced apart from the heat dissipation member; and
a heat transfer material layer between the lower chip structure and the heat transfer material layer and extending through the upper encapsulating layer and the adhesive layer,
wherein the heat transfer material layer, the adhesive layer, and the upper encapsulating layer are in contact with each other at an upper edge of an internal side surface of the adhesive layer.

16. The semiconductor package of claim 15, wherein the upper encapsulating layer comprises a laser debonding layer for laser debonding a carrier substrate and the lower package structure.

17. The semiconductor package of claim 15, wherein a thickness of the upper encapsulating layer is greater than a thickness of the adhesive layer.

18. The semiconductor package of claim 15, wherein the upper encapsulating layer comprises at least one of polybenzoxazole (PBO), polyimide (PI), or phenol.

19. A semiconductor package comprising:
a lower package structure including a lower redistribution structure, a lower chip structure on the lower redistribution structure, an upper encapsulating layer on the lower chip structure, and a plurality of posts electrically connected to the lower redistribution structure;
a heat dissipation member and an upper chip structure adjacent each other on the lower package structure;
a heat transfer material layer between the lower chip structure and the heat dissipation member and extending through the upper encapsulating layer; and
upper connection bumps extending through the upper encapsulating layer and electrically connecting the plurality of posts and the upper chip structure.

20. The semiconductor package of claim 19, further comprising an adhesive layer and a laser blocking layer covering an upper surface of the lower chip structure between the lower chip structure and the upper encapsulating layer.

21.-25. (canceled)
